(19) United States
(12) Patent Application Publication
(10) Pub. No.: US 2007/0077740 A1
(43) Pub. Date: Apr. 5, 2007

(54) Methods of fabricating fully silicide gate and semiconductor memory device having the same

(76) Inventor: Han Choon Lee, Seoul (KR)

Correspondence Address: Song K. Jung;MCKENNA LONG & ALDRIDGE LLP, 1900 K Street, N.W., Washington, DC, 20006, US

(21) Appl. No.: 11/320,949

(22) Filed: Dec. 30, 2005

(30) Foreign Application Priority Data
Oct. 4, 2005 (KR) 2005-0093012

(51) Int. Cl. H01L 21/22; H01L 21/38

(52) U.S. Cl. 438/558

(57) ABSTRACT

A method of fabricating a semiconductor device having a fully silicide gate comprises: forming a gate insulation film on a substrate; forming a patterned poly-silicon gate and an insulation layer on the gate insulation film; forming side wall spacers on both sides of the patterned poly-silicon gate; forming source/drain regions on the substrate at both sides of the poly-silicon gate having the side wall spacers; forming a silicide layer on the source/drain regions; forming an insulation film on the entire surface of the substrate; polishing the substrate to expose a top surface of the poly-silicon gate; amorphizing the exposed poly-silicon gate; and transforming the amorphized poly-silicon gate into a fully silicide gate.

### CROSS REFERENCE TO RELATED APPLICATION

This application claims the benefit of Korean Patent Application No. P2005-93012, filed on Oct. 4, 2005, which is hereby incorporated by reference as if fully set forth herein.

### BACKGROUND OF THE INVENTION

1. Field of the Invention

The present invention relates to a method of fabricating a semiconductor device, and more particularly, to a method of fabricating a fully silicide (FUSI) gate in a semiconductor device and a semiconductor device having the same.

2. Description of the Related Art

As semiconductor devices are miniaturized, a conventional poly-silicon gate shows shortcomings such as high gate resistance, deletion in a poly-silicon, and boron penetration. Therefore, a metal gate has been substituted for the poly-silicon gate. However, since a metal gate composed of pure TiN, TaN, or TiSiN has a nearly constant work function for NMOS or PMOS, the fully silicide (FUSI) gate in which silicide fully covers the gate has been utilized in the art. The FUSI gate has a work function within an operative range similar to that of a typical poly-silicon gate because of the dopants implanted on the gate.

FIGS. 1A through 1J are cross-sectional views illustrating a FUSI gate manufactured in accordance with a conventional method.

As shown in FIG 1A, a gate oxidation film 11 is formed on a silicon-on-insulator (SOI) substrate 10 having an isolation film (not shown).

As shown in FIG 1B, a poly-silicon gate layer 12 and an oxide hard mask layer 13 are formed on a gate oxidation film 11 through a gate lithography and etching process.

As shown in FIG. 1C, an expanded ion implantation process is performed.

As shown in FIG 1D, a side wall spacer 14 is formed.

As shown in FIG. 1E, a selective silicon growth is performed to form an expansion area 15 in a source/drain area on the substrate 10.

As shown in FIG 1F, impurities are implanted into the source/drain region.

As shown in FIG. 1 a silicide layer 16 having Co is formed on the source/drain region.

As shown in FIG. 1H, a nitride film and an oxidation film 17 are formed.

As shown in FIG. 1I, a chemical-mechanical polishing (CMP) process is performed to expose the gate.

Finally, as shown in FIG. 1J, the entire gate 18 is transformed to a FUSI gate made of NiSi.

The conventional FUSI gate described above with reference to FIGS. 1A through 1J has a work function having nearly the same operative range as that of a typical poly-silicon gate because of the dopants such as Ni implanted into the gate, as well as overcomes the aforementioned shortcomings of the typical poly-silicon gate.

However, in the aforementioned conventional semiconductor device having the FUSI gate, the gate is not entirely made of NiSi, but contains a significant amount of Ni₂Si. Therefore, gate resistance is increased and a leak current is generated.

### SUMMARY OF THE INVENTION

The present invention provides a method of fabricating a FUSI gate having an entirely uniform amount of NiSi and a semiconductor device having the same.

According to an aspect of the present invention, there is provided a method of forming a fully silicide gate, the method comprising processes of forming a poly-silicon layer on a substrate; patterning the poly-silicon layer to provide a gate pattern; amorphizing the gate pattern; and transforming the amorphized gate pattern into a fully silicide gate.

According to another aspect of the present invention, there is provided a method of fabricating a semiconductor device having a fully silicide gate, the method comprising processes of forming a gate insulation film on a substrate; forming a patterned poly-silicon gate and an insulation layer on the gate insulation film; forming side wall spacers on both sides of the patterned poly-silicon gate; forming source/drain regions on the substrate at both sides of the poly-silicon gate having the side wall spacers; forming a silicide layer on the source/drain regions; forming an insulation film on the entire surface of the substrate; polishing the substrate to expose a top surface of the poly-silicon gate; amorphizing the exposed poly-silicon gate; and transforming the amorphized poly-silicon gate into a fully silicide gate.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1J are cross-sectional views illustrating a conventional method of fabricating a fully silicide gate;

FIGS. 2A through 2I are cross-sectional views illustrating a method of fabricating a semiconductor device having a fully silicide gate according to the present invention; and

FIG. 3 is a graph showing a sheet resistance of a fully silicide gate according to the present invention.

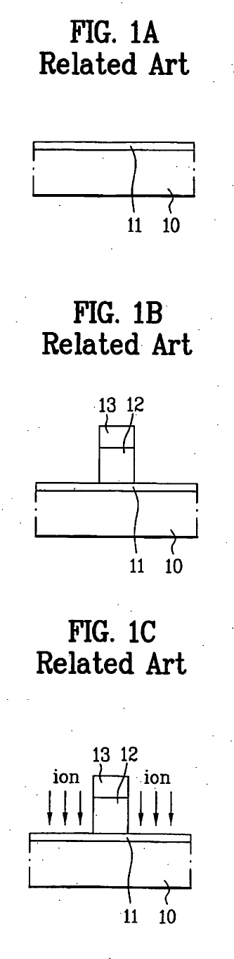

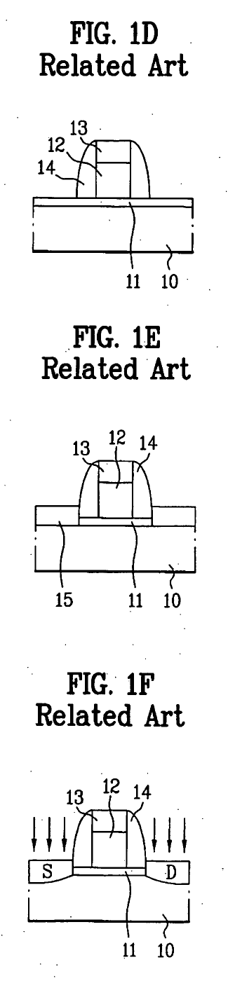

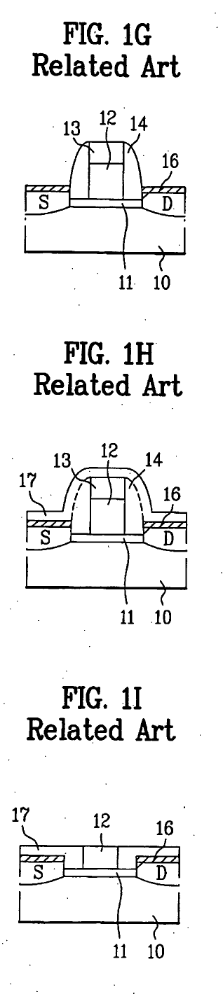

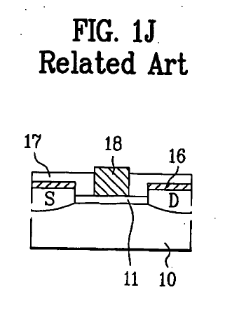

### DETAILED DESCRIPTION OF THE PREFERRED EMBODIMENTS

Hereinafter, exemplary embodiments of a method of fabricating a fully silicide (FUSI) gate and a semiconductor device having the same according to the present invention will be described in detail with reference to the accompanying drawings.

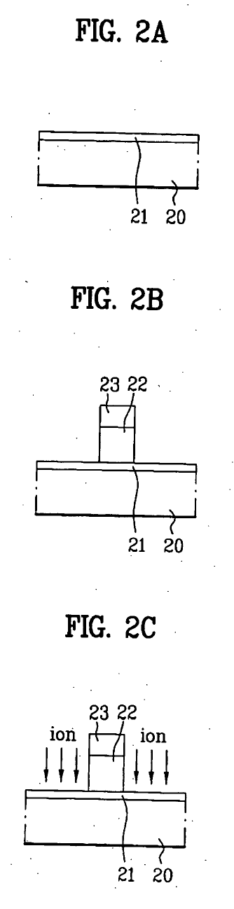

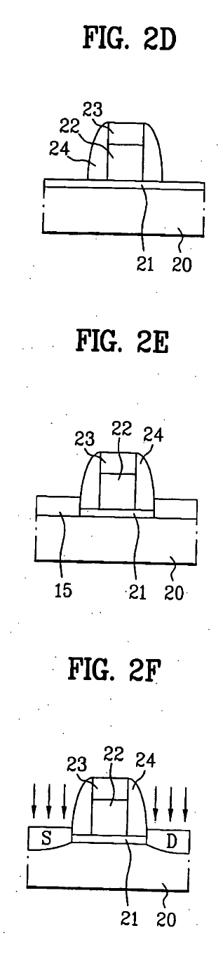

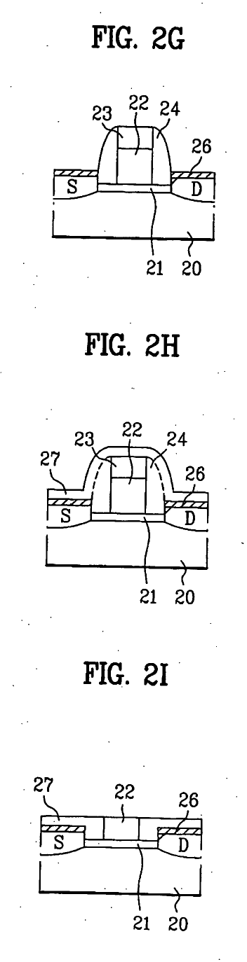

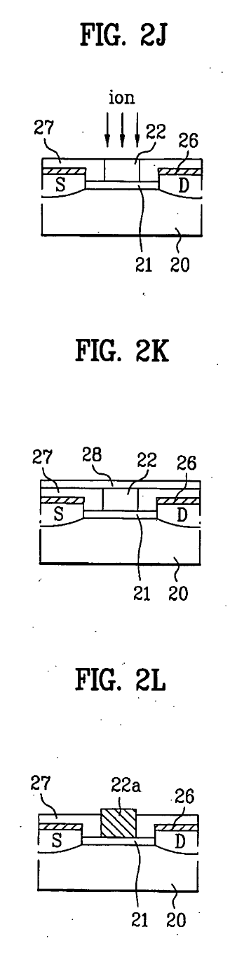

FIGS. 2A through 2L are cross-sectional views illustrating a method of fabricating a semiconductor device having a fully silicide gate according to the present invention.

First, as shown in FIG. 2A, a gate oxidation film 21 as a gate insulation film is formed on a silicon-on insulator (SOI) substrate 20 having an insulation film (not shown).

As shown in FIG. 2B, a poly-silicon gate 22 and an oxide hard mask 23 as an insulation layer are formed on the gate oxidation film 21. The poly-silicon gate 22 and the oxide hard mask 23 may be formed by using lithography and etching processes.

As shown in FIG. 2C, an expanded ion implantation process is performed on the portions of the substrate 20 disposed at both sides of the poly-silicon gate 22.

As shown in FIG. 2D, side wall spacers 24 are formed on both sides of the poly-silicon gate 22 including the oxide hard mask 23 on the substrate 20.

As shown in FIG. 2E, a selective silicon growth process is performed on portions of the substrate 20 at both sides of the poly-silicon gate 22, including the side wall spacers 24, to expand the source/drain regions 25.

As shown in FIG. 2F, impurity ions are implanted to the source/drain region 25 to form the source/drain S/D.

As shown in FIG. 2G, a Co metal layer is formed on the source/drain (S/D) regions of the substrate 20 and then thermally treated to form a silicide layer 26 on the source/drain S/D.

As shown in FIG. 2H, a nitride film and/or an oxidation film 27 are formed on the entire surface of the substrate 20 shown in FIG. 2G by using a deposition method.

As shown in FIG. 2I, a chemical mechanical polishing (CMP) is performed on the substrate 20 shown in FIG. 2H to expose the poly-silicon gate 22.

Then, as shown in FIG. 2J, Ge ions can be implanted to the exposed poly-silicon gate 22 to amorphize the poly-silicon gate 22. Meanwhile, before the implantation of the Ge ions, As, B, P, or In may be doped to the poly-silicon gate 22.

As shown in FIG. 2K, a metal layer made of a material such as Ti, Co, Ni, Mo, or Ta is formed on the entire surface of the substrate 20 shown in FIG. 2J and thermally treated to transform the poly-silicon gate 22 into a FUSI gate 22a as shown in FIG. 2L. After the thermal treatment, residual portions of the metal film remaining on the FUSI gate 22a may be removed through dry or wet etching.

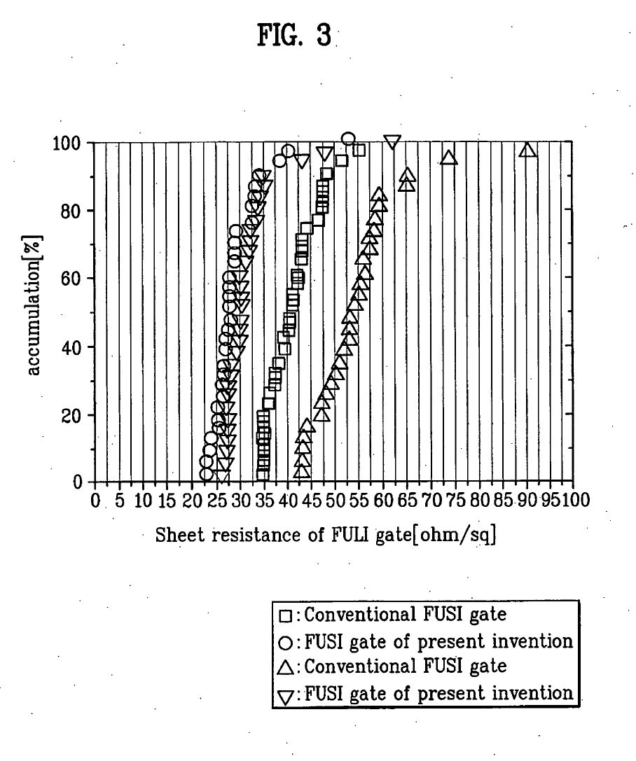

FIG. 3 is a graph showing a sheet resistance of the FUSI gate according to the present invention. The FUSI gate according to the present invention has a significantly lower sheet resistance in comparison with a conventional FUSI gate.

According to the present invention, a uniform amount of NiSi can be provided on the entire gate. Therefore, it is possible to reduce a sheet resistance of the gate and to prevent a leak current.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A method of forming a fully silicide gate, the method comprising:
forming a poly-silicon layer on a substrate;
patterning the poly-silicon layer to provide a gate pattern;
amorphizing the gate pattern; and
transforming the amorphized gate pattern into a fully silicide gate.

2. The method according to claim 1, wherein the amorphizing the gate pattern includes a step of implanting Ge ions into the gate pattern

3. The method according to claim 2, further comprising a step of adding a material selected from a group consisting of As, B, P and In into the gate pattern before the Ge ions are implanted.

4. The method according to claim 1, wherein the transforming the amorphized gate pattern into a fully silicide gate includes the steps of:
forming a metal layer on the amorphized gate pattern; and
heating the metal layer and the amorphized gate pattern.

5. The method according to claim 4, further comprising a step of removing residual portions of the metal layer remaining on the fully silicide gate after the step of thermally treating the metal layer and the amorphized gate pattern.

6. The method according to claim 5, wherein the residual portions are removed through dry or wet etching.

7. The method according to claim 4, wherein the metal layer is made of a material selected from a group consisting of Ti, Co, Ni, Mo, and Ta.

8. A method of fabricating a semiconductor device having a fully silicide gate, the method comprising:
forming a gate insulation film on a substrate;
forming a patterned poly-silicon gate and an insulation layer on the gate insulation film;
forming side wall spacers on both sides of the patterned poly-silicon gate;
forming source/drain regions on the substrate at both sides of the poly-silicon gate having the side wall spacers;
forming a silicide layer on the source/drain regions;
forming an insulation film on the entire surface of the substrate;
polishing the substrate to expose a top surface of the poly-silicon gate;
amorphizing the exposed poly-silicon gate; and
transforming the amorphized poly-silicon gate into a fully silicide gate.

9. The method according to claim 8, wherein the amorphization of the poly-silicon gate is performed by implanting Ge ions to the poly-silicon gate.

10. The method according to claim 9, further comprising a step of adding a material selected from a group consisting of As, B, P and In into the poly-silicon gate before the Ge ions are implanted.

11. The method according to claim 9, wherein the transforming the amorphized gate pattern into a fully silicide gate includes the steps of:
forming a metal layer on the amorphized gate pattern; and
heating the metal layer and the amorphized gate pattern.

12. The method according to claim 11, further comprising a step of removing residual portions of the metal layer remaining on the poly-silicide gate after the heating the metal layer and the amorphized gate pattern

13. The method according to claim 12, wherein the residual portions are removed through wet or dry etching.

14. The method according to claim 11, wherein the metal layer is made of a material selected from a group consisting of Ti, Co, Ni, Mo, and Ta.

15. A semiconductor device manufactured in accordance with claim 9.
